(19) United States
(12) Patent Application Publication
(10) Pub. No.: US 2014/0321485 A1
(43) Pub. Date: Oct. 30, 2014

(54) Resonator Based External Cavity Laser

(71) Applicant: OEwaves, Inc., Pasadena, CA (US)

(72) Inventors: David J. Seidel, Alta Loma, CA (US); Elijah B. Dale, Pasadena, CA (US); Andrey B. Matsko, Pasadena, CA (US); Lute Maleki, Pasadena, CA (US)

(73) Assignee: OEwaves, Inc., Pasadena, CA (US)

(21) Appl. No.: 14/262,539

(22) Filed: Apr. 25, 2014

Related U.S. Application Data
(60) Provisional application No. 61/816,102, filed on Apr. 25, 2013.

(51) Int. Cl. H01S 5/14; H01S 5/065

(52) U.S. Cl. CPC H01S 5/14; H01S 5/065
USPC 372/19; 372/44.01

(57) ABSTRACT

An external cavity laser comprises a gain medium and an external cavity resonator without the use of a semi-reflective surface placed between the gain medium and the resonator. Radiation from the gain medium is reflected back to the gain medium by one or more resonant backscattering regions of the resonator, such that the entire optical path between the gain medium and the external cavity resonator could be free from a reflective surface.

This application claims priority to U.S. Provisional Application No. 61/816,102, filed Apr. 25, 2013, which is incorporated by reference in its entirety.

### FIELD OF THE INVENTION

The field of the invention is laser technology.

### BACKGROUND

The background description includes information that may be useful in understanding the present invention. It is not an admission that any of the information provided herein is prior art or relevant to the presently claimed invention, or that any publication specifically or implicitly referenced is prior art.

All publications herein are incorporated by reference to the same extent as if each individual publication or patent application were specifically and individually indicated to be incorporated by reference. Where a definition or use of a term in an incorporated reference is inconsistent or contrary to the definition of that term provided herein, the definition of that term provided herein applies and the definition of that term in the reference does not apply.

Lasers have long been used to emit coherent light that can be focused into a small area over long distances. In order to create such coherent beams of light, flashes of light or electrical discharges are typically pumped into a gain medium to excite electrons that produce photons when they return to their relaxed state. By placing the gain medium between a cavity formed by a fully reflective mirror and a partially reflective mirror within an enclosed space, a device could be created that emits coherent light through the partially reflective mirror. U.S. Pat. No. 5,689,522 to Beach shows an exemplary laser diode with a gain medium disposed between two mirrors to create such an enclosed space.

Lasers could also be constructed using an external cavity located externally from the gain medium comprising a collimating lens and an external mirror. U.S. Pat. No. 6,115,401 to Scobey teaches an external cavity laser where the cavity is composed of a monolithic prism filter positioned between two lenses. While the amount of noise in external cavity lasers decrease with the length of the cavity, the amount of power in a coherent beam could be lost with a longer cavity.

Thus there remains a need for a system and method to produce an external cavity laser with a longer cavity.

### SUMMARY OF THE INVENTION

The following description includes information that may be useful in understanding the present invention. It is not an admission that any of the information provided herein is prior art or relevant to the presently claimed invention, or that any publication specifically or implicitly referenced is prior art.

In some embodiments, the numbers expressing quantities of ingredients, properties such as concentration, reaction conditions, and so forth, used to describe and claim certain embodiments of the invention are to be understood as being modified in some instances by the term “about.” Accordingly, in some embodiments, the numerical parameters set forth in the written description and attached claims are approximations that can vary depending upon the desired properties sought to be obtained by a particular embodiment. In some embodiments, the numerical parameters should be construed in light of the number of reported significant digits and by applying ordinary rounding techniques. Notwithstanding that the numerical ranges and parameters setting forth the broad scope of some embodiments of the invention are approximations, the numerical values set forth in the specific examples are reported as precisely as practicable. The numerical values presented in some embodiments of the invention may contain certain errors necessarily resulting from the standard deviation found in their respective testing measurements.

As used in the description herein and throughout the claims that follow, the meaning of “a,” “an,” and “the” includes plural reference unless the context clearly dictates otherwise. Also, as used in the description herein, the meaning of “in” includes “in” and “on” unless the context clearly dictates otherwise.

As used herein, and unless the context dictates otherwise, the term “coupled to” is intended to include both direct coupling (in which two elements that are coupled to each other contact each other) and indirect coupling (in which at least one additional element is located between the two elements). Therefore, the terms “coupled to” and “coupled with” are used synonymously.

Unless the context dictates the contrary, all ranges set forth herein should be interpreted as being inclusive of their endpoints, and open-ended ranges should be interpreted to include commercially practical values. Similarly, all lists of values should be considered as inclusive of intermediate values unless the context indicates the contrary.

The recitation of ranges of values herein is merely intended to serve as a shorthand method of referring individually to each separate value falling within the range. Unless otherwise indicated herein, each individual value is incorporated into the specification as if it were individually recited herein. All methods described herein can be performed in any suitable order unless otherwise indicated herein or otherwise clearly contradicted by context. The use of any and all examples, or exemplary language (e.g. “such as”) provided with respect to certain embodiments herein is intended merely to better illuminate the invention and does not pose a limitation on the scope of the invention otherwise claimed. No language in the specification should be construed as indicating any non-claimed element essential to the practice of the invention.

Groupings of alternative elements or embodiments of the invention disclosed herein are not to be construed as limitations. Each group member can be referred to and claimed individually or in any combination with other members of the group or other elements found herein. One or more members of a group can be included in, or deleted from, a group for reasons of convenience and/or patentability. When any such inclusion or deletion occurs, the specification is herein deemed to contain the group as modified thus fulfilling the written description of all Markush groups used in the appended claims.

The inventive subject matter provides apparatus, systems, and methods wherein an external cavity laser utilizes a total internal reflection (TIR) resonator to provide (1) a backscattering region that reflects radiation back towards the gain medium, and (2) a virtually long resonating cavity that reduces the noise of coherent radiation.

As used herein, a “gain medium” is an active laser medium that stimulates emission of electronic or molecular transitions to a lower energy state from a higher energy state previously populated by a pump source. Contemplated gain mediums include yttrium aluminum garnet (YAG), yttrium orthovanadate (YVO₄), sapphire (Al₂O₃), silicate or phosphate glasses doped with laser-active ions, nitrogen, argon, carbon monoxide, carbon dioxide, helium and neon (HeNe), gallium arsenide (GaAs), indium gallium arsenide (InGaAs), and gallium nitride (GaN). The gain medium is generally pumped with electrical currents or light that stimulates emission of amplified spontaneous emission (ASE) towards the resonator, and is configured to have a single reflective surface behind it, that reflects any electromagnetic radiation that hits the surface towards the resonator. For example, the gain medium could be a p-n junction in a semiconductor shaped in a rectangular fashion having a side facing the resonator painted with an anti-reflective coating, where the opposing side has a reflective surface that reflects photons through the gain medium towards the resonator. As used herein, an “amplified spontaneous emission (ASE)” has a Bose-Einstein distribution at a large number of photons. A Bose-Einstein distribution generally has an expectation value beyond its expectation value. The ASE is generated by the gain medium when a pump source, such as an electric current or a lamp, raises some electrons into an excited quantum state which then decays to emit a photon in accordance with a Bose-Einstein distribution.

When enough photons are sent through the gain medium, such that the net gain of photons from the gain medium exceed the total photon losses in the laser, the gain medium will emit coherent radiation. As used herein, a “coherent radiation” has a Poissonian distribution at a large number of photons, such as more than 100, 200, 1000, or 10000 photons. For a Poisson distribution, the expectation value (mean) and variance of the number of photons generally coincide.

As used herein, a “total internal reflection resonator” is a resonator where photons travel in a closed loop path that is coupled to an optical input and an optical output. The optical closed loop path is typically formed when photon radiation strikes an edge of the resonator at an angle larger than the critical angle with respect to the normal to the surface. When the refractive index is lower on the other side of the edge and the incident angle is greater than the critical angle, the photon radiation cannot pass through the edge of the resonator medium and is entirely reflective. Contemplated total internal reflection resonators include optical ring resonators and whispering gallery mode resonators, which are typically coupled to gain mediums through some sort of optical coupler, such as a prism or a waveguide. The resonator is preferably a monolithic resonator made from a single material, such as calcium fluoride, magnesium fluoride, fused silica, silicon nitride, or other type of crystal or glass or a polymer. The resonator is also generally made from a different material than the gain medium.

As a result of the closed optical loop properties of a total internal reflection resonator, the resonator virtually extends the length of the cavity of the external cavity laser by several times. The shape, size, and material of the resonator typically selects the resonator mode, and constructive interference will improve the Q-factor of the resulting coherent beam to over 5, 6, 7, 8, or even 9. A tuner could be coupled to the resonator that alters the resonator mode, for example by altering a temperature of the resonator or by altering a pressure applied to the resonator.

The resonator typically has one or more resonant backscattering regions that reflect a portion of the radiation back towards the gain medium. Backscattering is generally induced by surface inhomogeneties of the resonator, and could be increased by introducing additional inhomogeneties into the surface of the resonator. (See “Intracavity Rayleigh scattering in microspheres: limits imposed on quality-factor and mode coupling” by M. L. Gorodetsky, V. S. Ilchenko, A. D. Pryamikov, January 1999 SPIE Vol. 3611, incorporated herein by reference) Contemplated inhomogeneties include inhomogeneties by doping the resonator material, scratching a surface of the resonator, painting a surface of the resonator, stretching or compressing a portion of the resonator and using femtosecond lasers to introduce cavities or voids under a surface of the resonator, such as those discussed in co-pending application Ser. No. 14/206,822, titled “System and Methods for Removing Mode Families” incorporated herein by reference. Preferably, the inhomogeneties of the resonator induce enough backscattering to ensure that the photon gain of the gain medium exceeds the photon loss within the external cavity laser such that the system does not necessitate a partially reflective mirror or grating along. In a preferred embodiment, the sum total of resonant backscattering regions of the resonator reflect enough radiation from the gain medium back towards the gain medium to reduce the radiative loss of the gain medium, such that the total radiative loss of the gain medium is below the gain of the gain medium to achieve a lasing threshold. However, in some embodiments, a partially reflective mirror or grating could be positioned opposite the gain medium to reflect additional radiation back towards the resonator to the gain medium.

Contemplated reflectors include gratings that partially reflect radiation from the resonator back to the resonator and semi-reflective mirrors shaped in any suitable fashion (i.e. concave, convex). Exemplary gratings could be configured to select a wavelength of the coherent radiation to reflect back to the resonator while allowing other wavelengths through. The reflector is generally sized and disposed to reflect at least 2%, 5%, 25%, 40%, 50%, 60%, and 80% of the photons that hit it from the resonator back towards the resonator.

The entire optical path from the gain medium to the resonator cavity is free from any sort of reflective surface that reflects photons back towards their source. This is different from the optical pathways between the gain medium of a laser diode and a resonator, since a laser diode must have a reflective surface between the gain medium and the resonator to create the coherent radiation emitted from the laser diode. While the optical path between the gain medium to the resonator cavity must be free of reflective surfaces that reflect photons back to their source, the optical path could have devices that bend light along the optical path, such as a prism or a waveguide that guides the ASE from the gain medium to the resonator cavity. The optical path between the resonator cavity and the gain medium could also have a filter that selects a wavelength of the coherent radiation from the resonator, for example a diffraction grating or a band-pass filter. In this manner, a simple laser could be constructed from a gain medium, a resonator and a single reflective surface disposed behind the gain medium to form an external cavity laser without needing to dispose a reflective surface along the optical path between the gain medium and the resonator. The bandwidth of the filter in combination of the effective length of the resonator cavity leads to the ultimate noise performance of the external cavity laser.

Various objects, features, aspects and advantages of the inventive subject matter will become more apparent from the following detailed description of preferred embodiments, along with the accompanying drawing figures in which like numerals represent like components.

One should appreciate that the disclosed techniques provide many advantageous technical effects including producing a coherent beam of light with low noise without first producing a coherent beam of light with high noise, and utilizing an external gain cavity without first needing a laser.

### BRIEF DESCRIPTION OF THE DRAWING

FIG. 1 is a schematic of an exemplary external cavity laser having a whispering gallery mode (WGM) resonator and a prism.

FIG. 2 is another schematic of an exemplary external cavity laser having a simple rectangular total internal reflection resonator.

FIG. 3 is another schematic of an exemplary external cavity laser having a gain medium that is configured to emit both ASE and coherent light.

FIG. 4 is another schematic of an exemplary external cavity laser having a plurality of resonators.

### DETAILED DESCRIPTION

The following discussion provides many example embodiments of the inventive subject matter. Although each embodiment represents a single combination of inventive elements, the inventive subject matter is considered to include all possible combinations of the disclosed elements. Thus if one embodiment comprises elements A, B, and C, and a second embodiment comprises elements B and D, then the inventive subject matter is also considered to include other remaining combinations of A, B, C, or D, even if not explicitly disclosed.

The inventive subject matter provides apparatus, systems, and methods in which a gain medium and a resonator are configured to emit coherent light without the use of a reflective surface in between the gain medium and resonator to compose an external cavity laser.

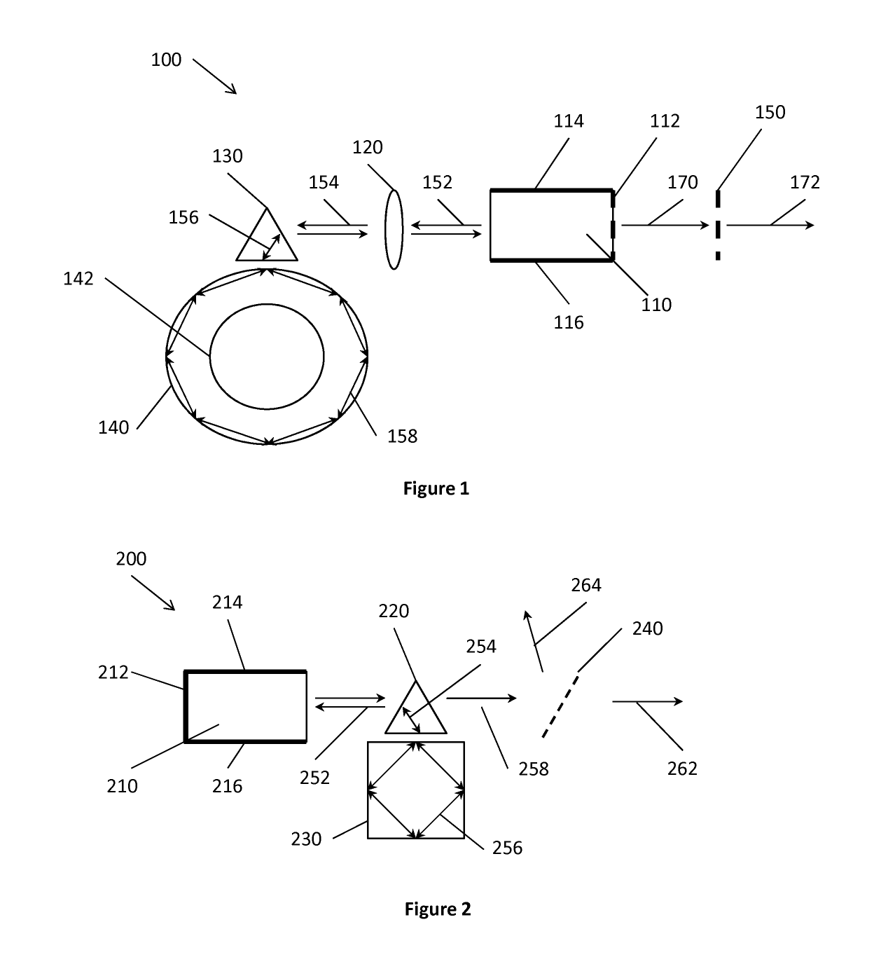

In FIG. 1, an external cavity laser 100 has a gain medium 110, a lens 120, an optical coupler 130, a resonator 140, and an optical filter 150. Gain medium 110 comprises indium gallium arsenide and resonator 130 comprises calcium fluoride, although other gain medium and resonator materials could be used without departing from the scope of the current invention. Surfaces 114 and 116 of gain medium 110 are completely reflective, and surface 112 of gain medium 110 is partially reflective, such that most ASE radiation emitted by gain medium 110 are emitted towards optical path 152, and a smaller minority are emitted towards optical path 170. The photon radiation from gain medium 110 is focused by lens 120 towards optical path 154, and is then refracted by optical coupler 130 along optical path 156 towards resonator 140. The entire optical path 152, 154, 156, and 158 is free from any reflective surface whatsoever. Optical coupler 130 is shown as a prism, but could be any sort of optical coupler that guides waves to/from resonator 110 to/from resonator 140.

Resonator 140 is shown as a WGM resonator, but could be any TIR resonator without departing from the scope of the invention. As photons travel along optical path 158 in the counter-clockwise direction, some of those photons will hit backscattering regions within the resonator, inducing those photons to travel clockwise back towards optical path 156, 154, and 152 into the gain medium. When the gains of gain medium 110 exceed the total losses of the external laser cavity system 100, gain medium 110 will emit coherent radiation.

Resonator 140 has tuner 142 located about 2 mm below the flat surface of resonator 140, which helps tune coherent laser beam 170 by manipulating the active modes of resonator 140. Tuner 142 is shown as a temperature plate that increments and decrements the temperature of resonator 140, but could also be a pressure plate that applies different amounts of pressure to a surface of resonator 140 or could apply electromagnetic fields to resonator 140 without departing from a scope of the invention. By manipulating the active modes of resonator 140 using tuner 142, usually through some sort of computer user interface, a user could select the mode of the resonator. A filter 150 is then placed in front of optical path 170 to filter out one or more wavelengths to produce output radiation 172.

In FIG. 2, an exemplary external cavity laser 200 has a gain medium 110, a prism 220, a total internal reflection resonator 230, and grating 240. Gain medium 110 has reflective surfaces 112, 114, and 116, while monolithic total internal reflection resonator 230 is appropriately shaped so as to sustain a closed ring path. While resonator 230 is shown as having four sides, resonator 230 could be shaped to have 3, 8, 12, 20, or more sides to sustain a closed ring path, and may even be shaped as a sphere or a ring. Gain medium 210 and resonator 230 are made of different materials, such that gain medium 210 produces ASE when stimulated by a pump source, such as electricity or light, and resonator 230 transmits a large amount of the optical spectrum while transmitting photons in closed ring optical path 256. The optical paths 252 and 254 between gain medium 210 and resonator 230 are free from any reflective surfaces. A grating 240 is placed opposing gain medium 210 on the other side of resonator 230 and is sized and disposed to allow some wavelengths through the grating towards output optical path 262 while reflecting other wavelengths towards optical path 264.

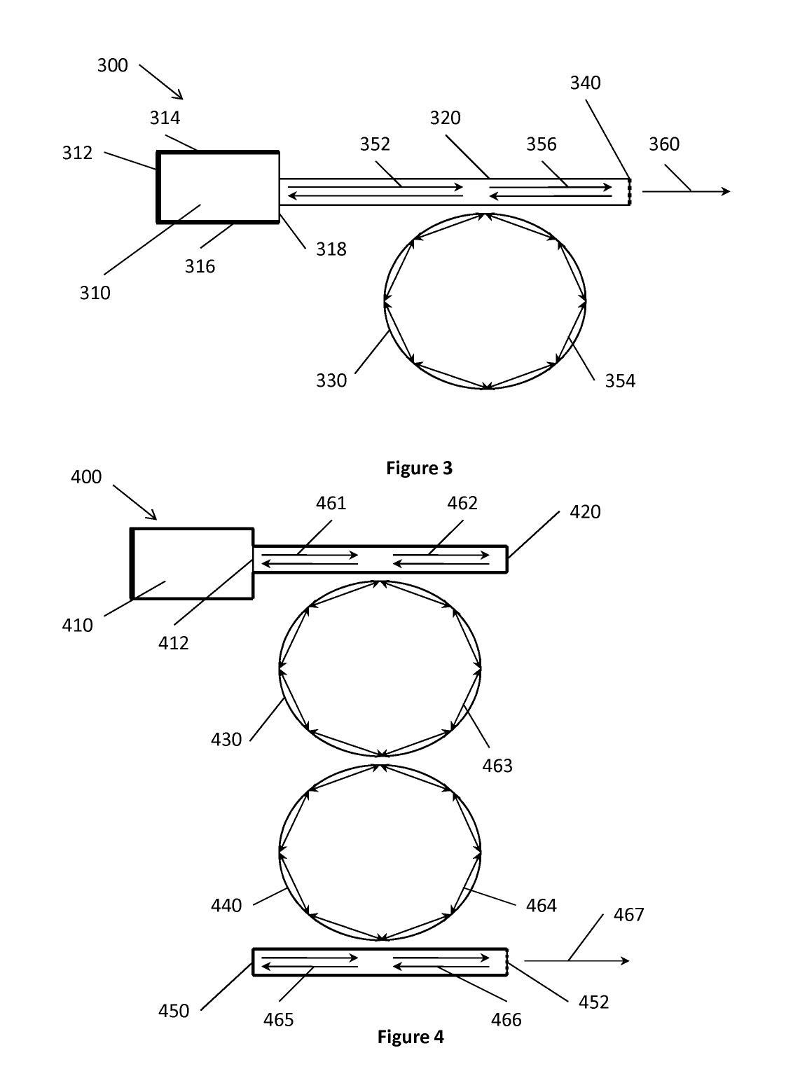

In FIG. 3, an alternate external cavity laser 300 is shown having gain medium 310, waveguide 320, resonator 330, and partially reflective mirror 340. Surfaces 312, 314, and 316 of gain medium 310 are fully reflective, and surface 318 of gain medium 310 has been coated with an anti-reflective coating. Radiation emitted by gain medium 310 travels along optical path 352 in waveguide 320, which is optically coupled to resonator 330, which artificially extends the length of the external cavity. Radiation travels along the closed path 354 of resonator 330, some of which is backscattered along optical path 352 to gain medium 310, and some of which is output to optical path 356, which hits partially reflective surface 340 to reflect back to gain medium 310. A portion of the radiation that hits partially reflective mirror 340 is output as output radiation 360.

In FIG. 4, another external cavity laser 400 is shown having gain medium 410, waveguide 420, first WGM resonator 430, second WGM resonator 440, and waveguide 450. The surfaces of gain medium 410 are fully reflective except for surface 412, where gain medium 410 abuts waveguide 420. Likewise, waveguide 420 has surfaces which are also fully reflective except where waveguide 420 abuts gain medium 410, forming a cavity within which photons travel. Radiation from gain medium 410 travels along optical path 461, which is optically coupled to first WGM resonator 430. Some of that radiation enters first WGM resonator 430 to travel along optical path 463, while other radiation continues to travel along optical path 462, which is reflected back towards gain medium 410 or enters first WGM resonator 430 traveling the opposing direction. Some of the radiation traveling along optical path 463 in first WGM resonator 430 is backscattered towards optical path 461 back to gain medium 410, some of the radiation is output towards optical path 462, and some of the radiation is output to second WGM resonator 440 to travel along optical path 464. Again, some of the radiation that enters second WGM resonator 464 is backscattered, while other radiation travels along the closed path, while still other radiation is output to either optical path 465 or 466 in waveguide 450.

Waveguide 450 is configured to have a fully reflective surface on all sides except for side 452, which is configured to be a partially reflective surface that sends radiation back along the paths to gain medium 410. A portion of the radiation travels through partially reflective surface 452 to be emitted as output radiation 467. The configuration of two abutting resonators with two waveguides creates an external cavity with a very long virtual length, since most of the photons will travel along closed loops 463 and 464 in resonators 430 and 440, respectively. The entire optical path 461, 463, 464, and 466 is free from any reflective surfaces.

It should be apparent to those skilled in the art that many more modifications besides those already described are possible without departing from the inventive concepts herein. Such external cavity lasers could be implemented with free space components, or integrated on an optical chip that incorporates the gain medium, the resonator, and waveguides/prisms without departing from the scope of the present invention. By tuning the resonator modes, for example with temperature, applied stress, or applied voltage to resonators made with photorefractive material, a widely tunable and low noise compact semiconductor laser could be constructed. The inventive subject matter, therefore, is not to be restricted except in the scope of the appended claims. Moreover, in interpreting both the specification and the claims, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced. Where the specification claims refers to at least one of something selected from the group consisting of A, B, C . . . and N, the text should be interpreted as requiring only one element from the group, not A plus N, or B plus N, etc.

What is claimed is:

1. An external cavity laser, comprising:
a gain medium that emits electromagnetic radiation;
a TIR resonator having a resonant backscattering region that reflects at least a portion of the radiation from the gain medium back to the gain medium; and
an optical pathway between the gain medium and the resonator, wherein the optical pathway is free from a reflective surface, wherein the radiation from the gain medium travels to the resonator via the optical pathway, and wherein backscattered radiation from the resonator travels to the gain medium via the optical pathway.

2. The external cavity laser of claim 1, wherein the gain medium comprises an anti-reflective coating.

3. The external cavity laser of claim 1, wherein the gain medium comprises a p-n junction having only a single reflective surface.

4. The external cavity laser of claim 1, wherein the resonator comprises a whispering gallery mode resonator.

5. The external cavity laser of claim 1, wherein the resonator comprises a monolithic resonator.

6. The external cavity laser of claim 5, wherein the resonator comprises a material different than the gain medium.

7. The external cavity laser of claim 1, wherein the resonant backscattering region comprises an inhomogeneous region introduced to the resonator material.

8. The external cavity laser of claim 6, wherein the inhomogeneous region is introduced by doping a portion of the resonator.

9. The external cavity of claim 6, wherein the inhomogeneous region is introduced by scratching a surface of the resonator.

10. The external cavity of claim 6, wherein the inhomogeneous region is introduced by painting a surface of the resonator.

11. The external cavity laser of claim 1, further comprising an optical coupler configured to guide radiation between the gain medium and the resonator along the optical pathway.

12. The external cavity laser of claim 11, wherein the optical coupler comprises at least one of a prism and a waveguide.

13. The external cavity laser of claim 1, further comprising a tuner that alters a temperature of the resonator to select a mode of the resonator.

14. The external cavity laser of claim 1, further comprising a tuner that alters a pressure applied to the resonator to select a mode of the resonator.

15. The external cavity laser of claim 1, further comprising a reflective surface positioned opposite the gain medium configured to reflect a portion of radiation emitted by the resonator back through the resonator to the optical pathway.

16. The external cavity laser of claim 15, wherein the reflective surface comprises a grating that selects a wavelength of the radiation to reflect.

17. The external cavity laser of claim 1, further comprising a filter disposed between the gain medium and the resonator to select a wavelength of the radiation.

18. The external cavity laser of claim 17, wherein the filter comprises a diffraction grating.

19. The external cavity laser of claim 17, wherein the filter comprises a band-pass filter.

20. The external cavity laser of claim 1, wherein a sum total of resonant backscattering regions of the resonator reflect enough radiation from the gain medium back to the gain medium to reduce the radiative loss of the gain medium below a gain of the gain medium to achieve a lasing threshold.
